(19) United States
(12) Patent Application Publication
(10) Pub. No.: US 2011/0073883 A1
(43) Pub. Date: Mar. 31, 2011

(54) LED LAMP

(75) Inventors: Hideharu Osawa, Kyoto (JP); Yasushi Mizuno, Kyoto (JP)

(73) Assignee: ROHM CO., LTD., Kyoto-shi, Kyoto (JP)

(21) Appl. No.: 12/995,038

(22) PCT Filed: May 28, 2009
(86) PCT No.: PCT/JP2009/059752

§ 371 Date: Nov. 29, 2010

(30) Foreign Application Priority Data
May 29, 2008 (JP) 2008-140320
Sep. 3, 2008 (JP) 2008-225957
Sep. 8, 2008 (JP) 2008-229939

(51) Int. Cl. H01L 27/15

(52) U.S. Cl. 257/88; 257/E27.12

(57) ABSTRACT

An LED lamp A1 is elongated in an axial direction x and includes a plurality of LED modules 30. Respective main light irradiation directions of the LED modules 30 are directed outward in radial directions that are perpendicular to the axial direction x, and the main light irradiation directions of the LED modules 30 are different from each other as viewed in the axial direction x. This arrangement provides a wider light irradiation range as viewed in the axial direction x.

### TECHNICAL FIELD

The present invention relates to an LED lamp.

### BACKGROUND ART

FIG. 20 is a sectional view showing an example of conventional LED lamp (see Patent Document 1). The LED lamp X is used as a substitute for a fluorescent lamp to be mounted to fluorescent lighting fixtures for general purpose lighting. The LED lamp X includes a cylindrical light-transmitting cover 93, a substrate 91, LED modules 92 and a terminal 94. The substrate 91 and the LED modules 92 are housed in the light-transmitting cover 93. The substrate 91 comprises a rectangular flat plate extending in the axial direction x of the LED modules 92. The plurality of LED modules 92 are mounted on the substrate 91. The terminal 94 is configured to be fitted into an inlet of a socket of a fluorescent lighting fixture. Electric power is supplied from the outside of the LED lamp X to the LED modules 92 via the terminal 94. Herein, the fluorescent lighting fixtures for general purpose lighting refer to lighting fixtures which are widely used for general indoor lighting, which utilize e.g. the commercial power supply of 100V or 200V in Japan, and to which straight-tube fluorescent lamps in accordance with JIS C7617 or circular fluorescent lamps in accordance with JIS C7618 are mounted.

However, in the conventional LED lamp X, the LED modules 92 are oriented in the same direction when viewed in the axial direction x, causing the light to be emitted in only one direction. Thus, the use of the LED lamp X involves a problem that light emission in a certain direction is insufficient and some areas cannot be illuminated brightly.

### DISCLOSURE OF THE INVENTION

### Problems to be Solved by the Invention

The present invention has been conceived under the circumstances described above. It is therefore an object of the present invention to provide an LED lamp which is capable of providing a wider light irradiation range as viewed in the axial direction.

### Means for Solving the Problems

To solve the above-described problem, the present invention takes the following technical measures.

An LED lamp according to a first aspect of the present invention is elongated in an axial direction and includes a plurality of LED chips. Each of the LED chips is arranged to emit light having a main light irradiation direction directed outwards of a radial direction perpendicular to the axial direction, where the main light irradiation directions of the LED chips are different from each other as viewed in the axial direction.

In a preferred embodiment of the present invention, the LED lamp a further includes a metal support member supporting the LED chips and arranged inwards of the radial directions with respect to the LED chips.

In a preferred embodiment of the present invention, the LED lamp includes a reflective surface, where the radial directions include a first direction passing through one of the LED chips, and the reflective surface is configured to, as receding in the first direction, become farther away from the relevant LED chip in a second direction perpendicular to the first direction.

In a preferred embodiment of the present invention, the LED lamp includes a reflective member made of a metal and provided with the reflective surface, where the reflective member and the metal support member are connected to each other.

In a preferred embodiment of the present invention, the LED lamp includes at least one multiple light source in which at least two LED chips having different main light irradiation directions, among the plurality of the LED chips, are arranged at the same position in the axial direction.

In a preferred embodiment of the present invention, a plurality of the multiple light sources are provided and spaced apart from each other in the axial direction.

Other features and advantages of the present invention will become more apparent from the detailed description given below with reference to the accompanying drawings.

### BRIEF DESCRIPTION OF THE DRAWINGS

FIG. 1 is a perspective view of a principal portion of an LED lamp according to a first embodiment of the present invention;

FIG. 2 is a sectional view taken along lines II-II in FIG. 1;

FIG. 3 is a side view of a principal portion of an LED lamp according to a second embodiment of the present invention;

FIG. 4 is a partially cut away plan view of an LED lamp according to a third embodiment of the present invention;

FIG. 5 is a partially cross-sectional perspective view of part of the LED lamp shown in FIG. 4;

FIG. 6 is a plan view of a principal portion of the LED lamp shown in FIG. 4;

FIG. 7 is a perspective view showing a material board used for a manufacturing process of the LED lamp shown in FIG. 4;

FIG. 8 is a perspective view showing the step of mounting LED modules on the material board in the manufacturing process of the LED lamp shown in FIG. 4;

FIG. 9 is a perspective view showing the step of cutting the material board in the manufacturing process of the LED lamp shown in FIG. 4;

FIG. 10 is a perspective view showing the step of bending the cut material board in the manufacturing process of the LED lamp shown in FIG. 4;

FIG. 11 is a front view of an LED lamp according a fourth embodiment of the present invention;

FIG. 12 is a sectional view taken along lines XII-XII in FIG. 11;

FIG. 13 is a side view of the LED lamp shown in FIG. 11, as viewed in the axial direction;

FIG. 14 is a plan view showing the step of punching holes in a metal plate;

FIG. 15 is a perspective view showing the step of forming a support member;

FIG. 16 is a plan view showing the step of forming cylindrical portion at an end of the support member;

FIG. 17 is a plan view of the support member after a cylindrical portion is formed at each end thereof;

FIG. 18 is a front view showing the step of mounting Peltier devices;

FIG. 19 is a sectional view showing the step of attaching a substrate on a side plate portion; and

FIG. 20 is a sectional view of a principal portion of a conventional LED lamp.

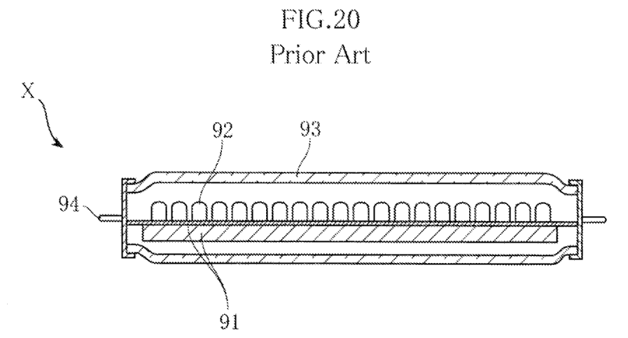

### BEST MODE FOR CARRYING OUT THE INVENTION

Preferred embodiments of the present invention are described below with reference to accompanying drawings.

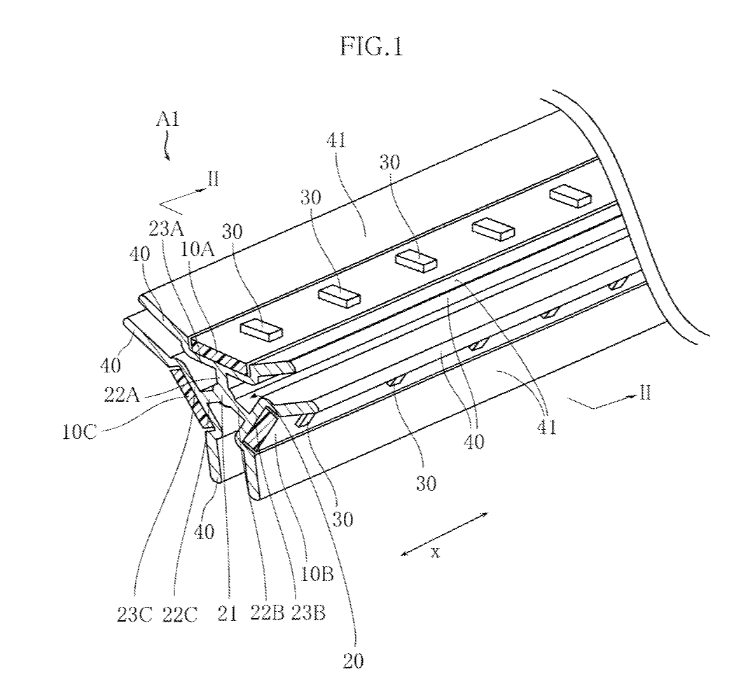

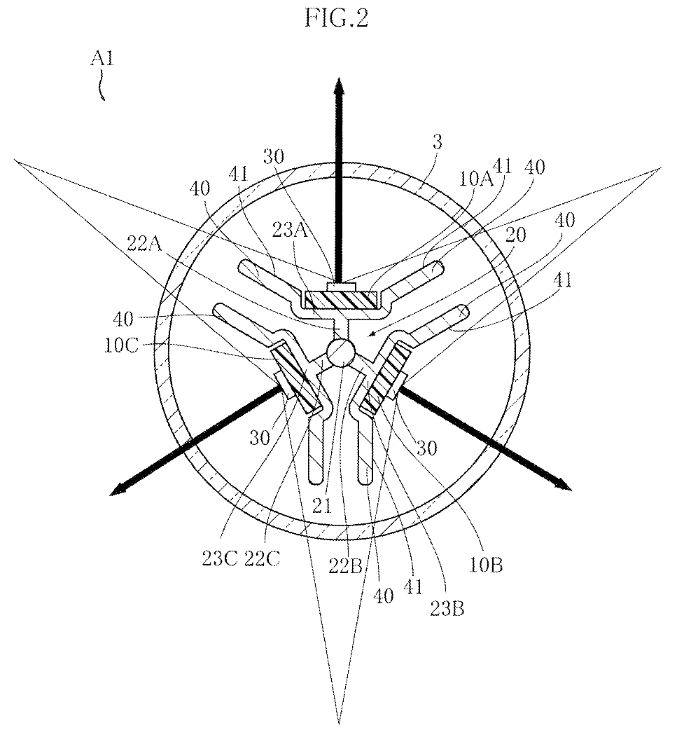

FIGS. 1 and 2 show an LED lamp according to a first embodiment of the present invention. FIG. 1 is a perspective view of a principal portion of an LED lamp A1 according to this embodiment. FIG. 2 is a sectional view taken along lines II-II in FIG. 1.

The LED lamp A1 is used as a substitute for a fluorescent lamp, for example. The LED lamp A1 includes a cylindrical light-transmitting cover 3, a metal support member 20, substrates 10A, 10B, 10C, LED modules 30 and reflective members 40. The metal support member 20, the substrates 10A, 10B, 10C and the LED modules 30 are housed in the cylindrical light-transmitting cover 3.

The metal support member 2 shown in FIGS. 1 and 2 is made of A1, for example, and has an elongated shape. The metal support member 20 may be annular. The metal support member 20 includes a columnar portion 21, leg portions 22A, 22B, 22C and plate portions 23A, 23B, 23C. The columnar portion 21 extends in a predetermined direction. In this embodiment, the direction which extends through the center of the columnar portion 21 and in which the columnar portion 21 extends is the axial direction according to the present invention.

The leg portions 22A, 22B and 22C have a flat plate-like shape elongated in the axial direction x. When viewed in the axial direction x, the leg portions 22A, 22B and 22C extend radially from the center of the columnar portion 21 in radial directions perpendicular to the axial direction x. Each of the leg portions 22A, 22B and 22C is arranged to form an angle of 120 degrees with the adjacent one of the leg portions. The plate portions 23A, 23B and 23C are positioned on the outer side of the leg portions 22A, 22B and 22C in the radial directions, respectively. The plate portions 23A, 23B and 23C are connected at right angles to the leg portions 22A, 22B and 22C, respectively.

The substrates 10A, 10B and 10C are fixed to the outer side of the plate portions 23A, 23B and 23C in the radial directions, respectively. Each of the substrates 10A, 10B and 10C comprises a flat plate of an elongated rectangular shape made of e.g. glass-fiber-reinforced epoxy resin. Each of these substrates is provided with metal wiring layers (now shown) formed on the obverse surface (the upper side in the figures for the substrate 10A) and the reverse surface (the lower side in the figures for the substrate 10A) to be spaced apart from each other, through-holes and so on. The substrates 10A, 10B and 10C may be made by using aluminum covered with an insulating film.

As shown in FIG. 1, the LED modules 30 are arranged on each of the substrates 10A, 10B and 10C at predetermined intervals in the axial direction x. As shown in FIG. 2, the LED modules 30 are mounted on the outer surfaces of the substrates 10A, 10B and 10C in the radial directions. Each of the LED modules 30 includes an LED chip (light emitting diode), leads spaced apart from each other, a wire and a resin package.

The LED chip has a lamination structure made up of an n-type semiconductor layer, a p-type semiconductor layer and an active layer sandwiched between these layers. The LED chip can emit blue light when made of a GaN-based semiconductor. The resin package contains a fluorescent substance mixed therein. Depending on the kinds of the fluorescent substance, LED modules can emit light of different color temperatures.

In order for the LED module 30 to emit white light, a yellow-light emitting substance, that emits yellow light when excited by blue light, is employed as the fluorescent substance. The LED module 30 can emit white light because of the blue light from the LED chip and the yellow light from the yellow fluorescent substance.

The fluorescent substance may not be a yellow fluorescent substance but may be a mixture of fluorescent substances. The mixture consists of a red fluorescent substance that emits red light when excited by blue light, and a green fluorescent substance that emits green light when excited by blue light. The LED module 30 can emit white light because of the blue light from the LED chip and red light and green light from the mixture of the fluorescent substances. With this arrangement, the LED module 30 can emit white light with a higher color rendering index than when the resin package contains a yellow fluorescent substance.

By appropriately adjusting the mixing ratio of the fluorescent substance in the resin package, the LED module 30 can emit white light with a color temperature of 3000K (incandescent color) or white light with a color temperature of 670K (daylight color), for example.

In this embodiment, the LED modules 30 are so arranged as to emit light outwards in the radial directions with respect to the center of the columnar portion 21. Specifically, for example, the LED modules 30 mounted on the substrate 10A are arranged to emit light upward in FIG. 2. The LED modules 30 mounted on the substrate 10B and the LED modules mounted on the substrate 10C are arranged to emit light diagonally to the lower right and to the lower left in FIG. 2, respectively. These light irradiation directions of the LED modules 30 are indicated by arrows in the figure. These directions are the main light irradiation directions of the LED chips, defined in the present invention. As viewed in the axial direction x, the main light irradiation directions of the LED chips defined in the present invention refer to a direction extending through the center of the range irradiated with the light from the LED modules 30.

The reflective member 40 is connected to each end of the plate portion 23A, 23B, 23C. An angle of about 150 degrees is defined between each of the reflective members 40 and the relevant plate portion 23A, 23B, 23C. The reflective member 40 is made of e.g. A1. The reflective member 40 has a reflective surface 41. The reflective surface 41 causes the light emitted from the LED modules 30 to travel in the radial direction. As shown in the sectional view of FIG. 2, the reflective surface 41 is configured in a manner such that as proceeding away from the columnar portion 21 in the radial direction extending through the relevant LED module 30, the reflective surface 41 becomes gradually farther away from the LED modules 30 in the direction which is perpendicular to the radial direction. Although the reflective surface 41 in this embodiment is a flat surface, it may be a curved surface, for example.

The light-transmitting cover 3 is made of a transparent material. Thus, the light-transmitting cover 3 allows light from the LED modules 30 to pass therethrough.

The advantages of the LED lamp A1 are described below.

The LED lamp A1 according to the present embodiment provides a wider light irradiation range, as viewed in the axial direction x. Heat generated at the LED chips is dissipated to the outside of the LED lamp A1 from the metal support member 20, whereby heat dissipation of the LED lamp A1 is promoted. Part of the light emitted from the LED modules 30 is reflected by the reflective surfaces 40 to travel outwards in the radial directions. This enhances the luminance of the light emitted from the LED lamp A1. Heat generated at the LED chips is dissipated to the outside of the LED lamp A1 also from the reflective members 40. This further promotes the heat dissipation of the LED lamp A1.

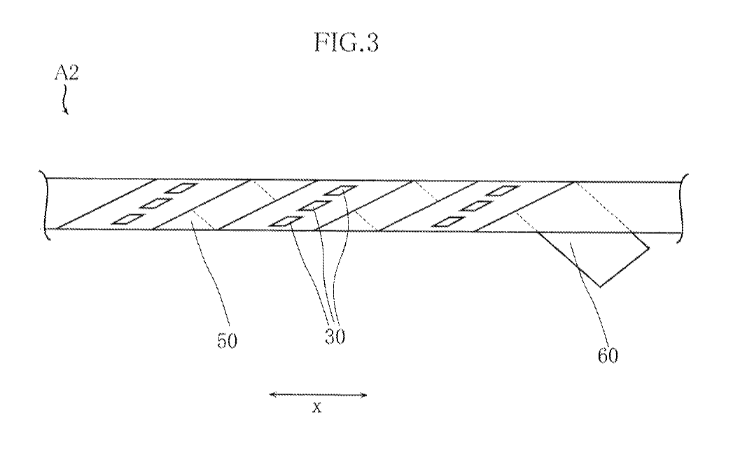

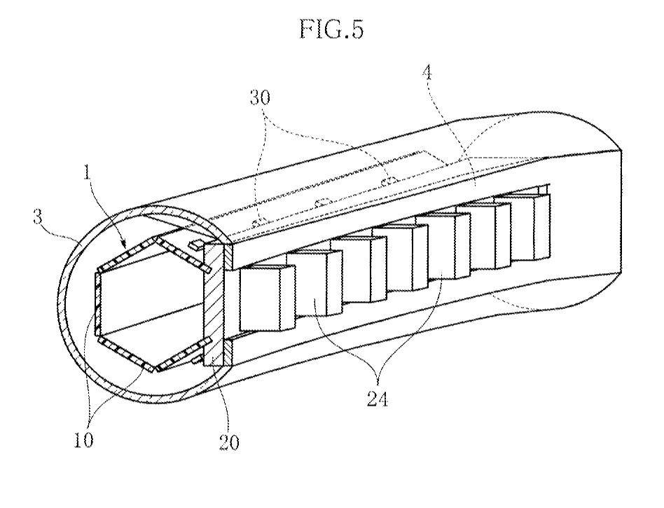

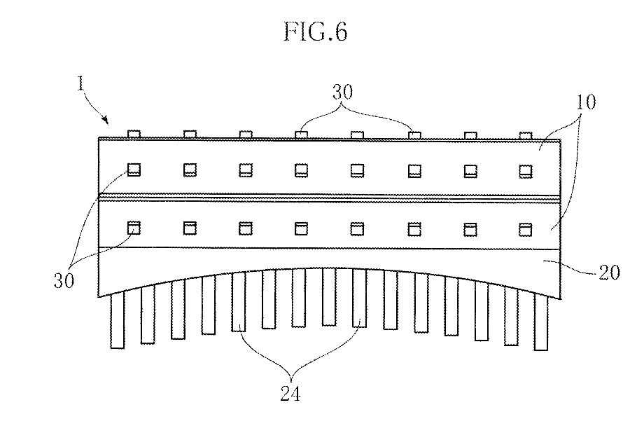

FIGS. 3-19 illustrate other embodiments of the LED lamp according to the present invention. In these figures, the elements which are identical or similar to those of the foregoing embodiment are designated by the same reference signs as those used for the foregoing embodiment.

FIG. 3 shows an LED lamp according to a second embodiment of the present invention. The LED lamp A2 of this embodiment comprises a cylindrical bar 50 around which a tape light 60 carrying LED modules 30 is wound. The LED lamp A2 having this structure can emit light from the entirety of the circumference, as viewed in the axial direction x.

The LED lamp according to the present invention is not limited to the foregoing embodiments. The specific structure of each part of the LED lamp according to the present invention can be varied in design in various ways. For instance, a plurality of LED modules may be provided on each of the two faces of a single substrate. In this case, it is not necessary to prepare a plurality of substrates to make a single LED lamp, which allows reducing the manufacturing cost of the LED lamp.

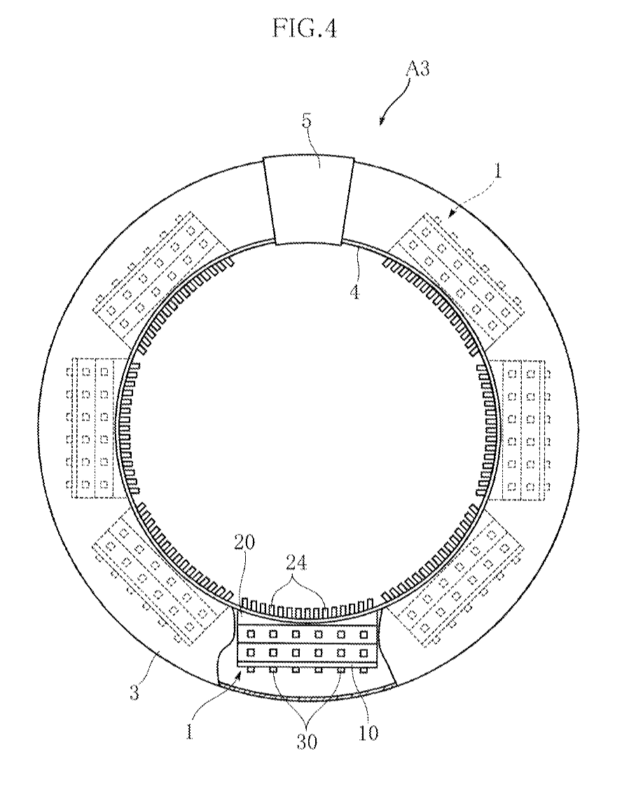

FIGS. 4-6 illustrate an LED lamp according to a third embodiment of the present invention. The LED lamp A3 of this embodiment includes a plurality of light emitting modules 1, a metal support member 20, a light-transmitting cover 3, a bracket 4 and a base 5. The LED lamp A3 is mounted to a non-illustrated lighting fixture adapted to circular fluorescent lamps.

Each of the light emitting modules 1 is a tubular member comprising a plurality of substrates 10 connected to each other at the longitudinal edges. Each of the substrates 10 is made of a glass-fiber-reinforced epoxy resin, for example, and has an elongated rectangular shape. Adjacent ones of the substrates 10 are connected to each other at their longitudinal edges via a thin-walled portion. On each of the substrates 10, a plurality of LED modules 30 are mounted, as oriented outwards, at equal intervals in the longitudinal direction of the substrate. Each of the LED modules 30 includes an LED chip (not shown) connected to a lead made of a metal (not shown) and sealed with a light-transmitting resin (not shown). These LED modules 30 are connected to a wiring pattern (not shown) formed on the substrate 10. The light emitting modules 1 are attached to the metal support member 20.

In this embodiment, as an example, the light emitting modules 1 each comprising five substrates 10 are attached to the metal support member 20. The metal support member 20 and the bracket 4 are formed with wiring patterns (now shown) electrically connected to the substrates 10. With this arrangement, electric power from a power supply is supplied from the base 5 to the LED modules 30 via the bracket 4, the metal support member 20 and the substrates 10. The light emitting modules 1 are housed in the light-transmitting cover 3. Each light emitting module 1 exhibits a substantially hexagonal cross section when viewed as an integral part with the metal support member 20. Thus, with the plurality of light emitting modules 1, light from the LED chips (not shown) incorporated in the LED modules 30 is directed in various directions in which the substrates 10 are oriented.

The metal support member 20 is made of e.g. A1 and bonded to the substrates 10 that form two ends of each light emitting module 1. The metal support member 20 is formed with a plurality of projections 24. The projections 24 are exposed from the light-transmitting cover 3 and the bracket 4 toward the center. With this metal support member 20, heat generated from the LED modules 30 is efficiently transmitted to the metal support member 2 via the substrates 10. Since the projections 24 exposed to the outside increases the contact area of the metal support member 20 with air, heat is dissipated quickly. The main body and projections of the heat dissipation member may be made of different metals, and a Peltier device may be provided at the portion where these are bonded together to enhance the heat dissipation effect.

The light-transmitting cover 3 is made of e.g. glass or a polycarbonate resin and allows the light emitted from the light emitting modules 1 to pass therethrough to the outside while protecting the light emitting modules 1 housed therein. The light-transmitting cover 3 is formed with an opening on the inner circumferential side. The base 5 is attached to a portion of the light-transmitting cover 3. A power supply connector of a non-illustrated lighting fixture is connected to the base 5.

The bracket 4 is annular and attached to the opening on the inner circumferential side of the light-transmitting cover 3. The metal support member 20 is bonded to the bracket 4. With the support by the bracket 4, the light emitting modules 1 are arranged within the light-transmitting cover 3 annularly at predetermined intervals. The bracket 4 is electrically connected to the base 5, thereby also serving as a path to supply electric power to the light emitting modules 1.

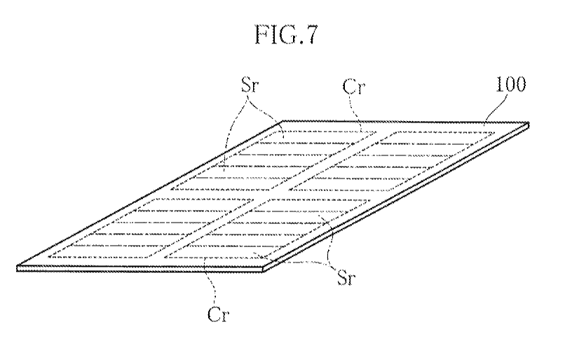

FIGS. 7-10 show an embodiment of a method for manufacturing the LED lamp 3.

First, as shown in FIG. 7, a rectangular material board 100 which can provide a plurality of substrates 10 is prepared. Then, a plurality of continuous rectangle regions Cr, each consisting of a plurality of portions to become substrates 10 connected together at the longitudinal edges thereof, are defined in the material board 100. In the figure, the boundaries between the rectangular portions Sr, which correspond to the substrates 10, are indicated by single-dashed lines, whereas the outer edges of the continuous rectangle regions Cr are indicated by broken lines.

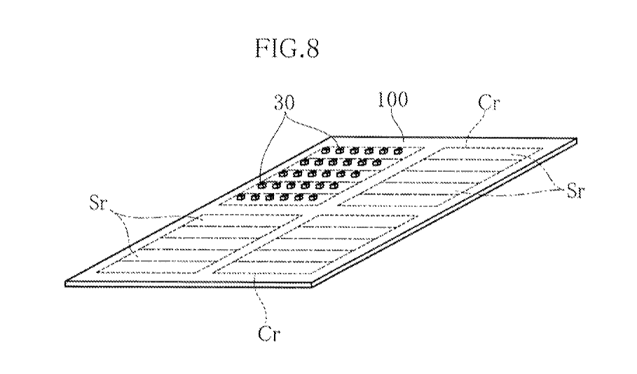

Then, as shown in FIG. 8, a plurality of LED modules 30 are mounted on the material board 100 in each of the rectangular portions Sr at equal intervals in the longitudinal direction of the rectangular portion.

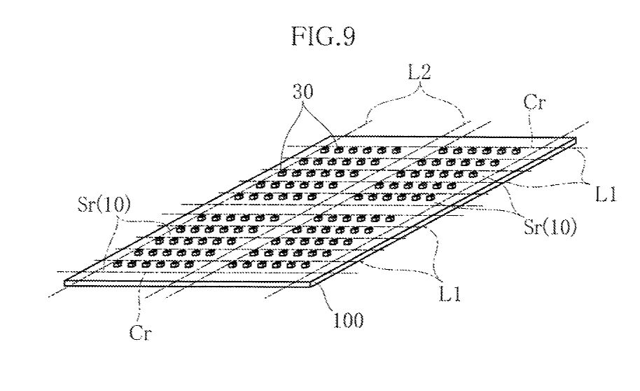

Then, as shown in FIG. 9, by using e.g. a dicing saw or laser, grooves are formed in the material board 100 along the boundary lines L1 between the rectangular portions Sr indicated by the single-dashed lines. As for the continuous rectangle regions Cr overall, the material board 100 is cut along the cutting lines L2 corresponding to the outer edges of these regions indicated by the broken lines. As a result, the continuous rectangle regions Cr are cut out of the material board 100. In this state, each of the continuous rectangle regions Cr includes a plurality of rectangular portions Sr connected to each other via thin-walled portions where the grooves are formed along the boundary lines L1.

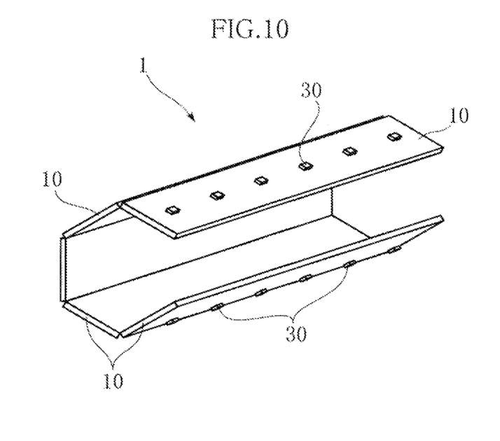

Then, as shown in FIG. 10, each of the continuous rectangle regions Cr cut out of the material board 100 is formed into a tubular shape by bending along the grooves, which serve as the boundaries between the substrates (rectangular portions Sr). In this way, a light emitting module 1 is obtained in which the LED modules 30 on each of the substrates 10 are oriented to the outside.

In the LED lamp A3 according to this embodiment, a tubular light emitting module 1 is obtained by bending the continuous rectangle region Cr at the boundaries between the rectangular portions Sr. Since the plurality of light emitting modules 1 are arranged annularly, light is emitted uniformly in various directions in which the substrates 10 are oriented even when each of the LED modules 30 has high directivity.

As for the manufacture of the LED module 1, the tubular light emitting module 1 can be completed just by cutting a continuous rectangle region Cr out of a rectangular material board 100 and bending the continuous rectangle region Cr along grooves. This allows reducing the remnants of the material board as small as possible as compared with cutting a curved substrate out of a rectangular material board, for example. Thus, the productivity and yield are easily enhanced.

The present invention is not limited to the foregoing embodiment. The specific structure of each part of the LED lamp according to the present invention can be varied in design in various ways.

For instance, one or a plurality of light emitting modules 1 according to the foregoing embodiment may be housed in a light-transmitting cover of a straight-tube shape and mounted to a non-illustrated lighting fixture adapted to straight-tube fluorescent lamps.

The elongated rectangle regions may be defined in the material board such that no space is left between the adjacent elongated rectangle regions and the cutting lines lie on the boundary between the rectangle regions. This arrangement allows a larger number of substrates connected to each other at the longitudinal edges to be cut out of a single material board.

The LED chips may be mounted directly on the substrate.

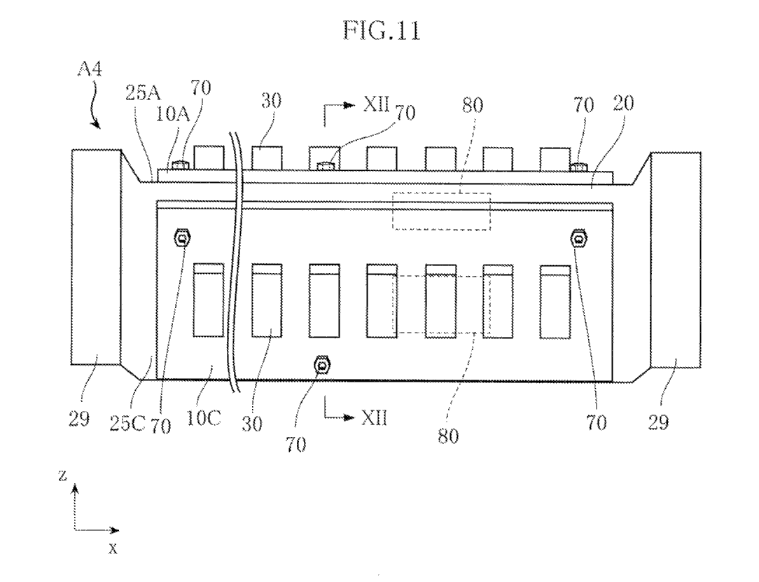

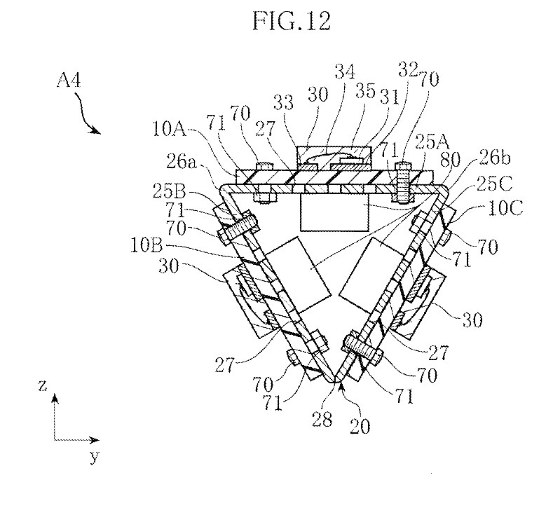

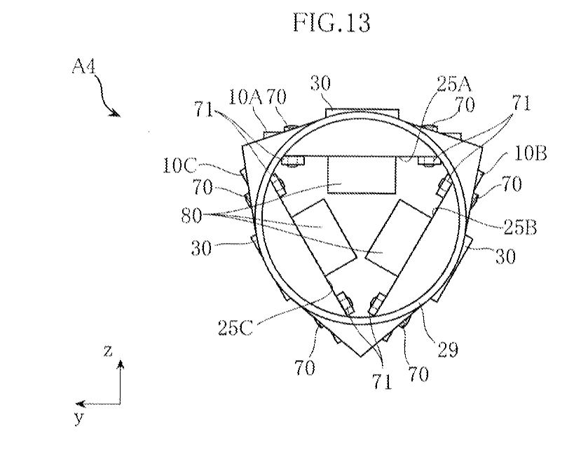

FIGS. 11-13 show an LED lamp according to a fourth embodiment of the present invention. The LED lamp A4 shown in FIGS. 11-13 includes a metal support member 20, substrates 10A, 10B, 10C, a plurality of LED modules 30, a plurality of screws 70, a plurality of nuts 71 and a plurality of Peltier devices 80. The LED lamp A4 may be housed in a light-transmitting cover (not shown) of a straight-tube shape and mounted to a fluorescent lighting fixture for general purpose lighting for use as a substitute for a straight-tube fluorescent lamp. This LED lamp has an elongated shape extending in the axial direction x overall. As shown in FIG. 12, the LED lamp 4 has a 120-degree rotational symmetry with respect to a non-illustrated axis extending in the axial direction x. For convenience of explanation, the height direction z of the substrate 10A is indicated in FIG. 11 in addition to the axial direction x, whereas the width direction y and the height direction z of the substrate 10A are indicated in FIGS. 12 and 13.

The metal support member 20 is made of e.g. A1, includes side plate portions 25A, 25B, 25C, a bonding portion 28 and cylindrical portions 29, and has a tubular shape elongated in the axial direction x.

The side plate portion 25A has a constant width in the width direction y and a constant thickness of about 1 to 2 mm in the height direction z, and is elongated in the axial direction x. An edge of the side plate portion 25A in the width direction y is connected to the side plate portion 25B via a bent portion 26a. The side plate portion 25A and the side plate portion 25B form an angle of 60° at the bent portion 26a. The other edge of the side plate portion 25A in the width direction y is connected to the side plate portion 25C via a bent portion 26b. The side plate portion 25A and the side plate portion 25C form an angle of 60° at the bent portion 26b. As shown in FIG. 12, the side plate portions 25B and 25C each have a configuration obtained by turning the side plate portion 25A through 120° in different directions. An edge of the side plate portion 25B and an edge of the side plate portion 25C are welded together at the bonding portion 28. Peltier devices 80 are attached to the inner surfaces of the side plate portions 25A, 25B, and 25C at positions close to the ends spaced in the axial direction x. Each of the side plate portions 25A, 25B and 25C is formed with a plurality of punched holes 27.

The punched holes 27 are formed to penetrate the side plate portions 25A, 25B and 25C in the thickness direction. For instance, the punched holes 27 are so formed that five punched holes are aligned in each row extending in the width direction of the side plate portions 25A, 25B and 25C.

As shown in FIG. 13, the cylindrical portions 29 are annular as viewed in the axial direction x and provided at each end of the metal support member 20 in the axial direction x. A cylindrical base (not shown), for example, is attached to the cylindrical portions 29.

The substrates 10A, 10B and 10C are made of e.g. glass-fiber-reinforced epoxy resin and have a rectangular shape having a constant width and elongated in the axial direction x. The substrate 10A is fixed to the outer surface of the side plate portion 25A with three screws 70 and three nuts 71. The substrate 10B is fixed to the outer surface of the side plate portion 25B with three screws 70 and three nuts 71. The substrate 10C is fixed to the outer surface of the side plate portion 25C with three screws 70 and three nuts 71. As illustrated in FIG. 11, of the three screws 70 that fix the substrate 10C, two screws fix each end of the substrate 10C in the axial direction x, whereas one screw fixes a central portion of the substrate 10C in the axial direction x. The two screws 70 fixing each end and the screw 70 fixing the central portion are spaced apart from each other in the width direction of the substrate 10C, which is favorable for the reliable fixing of the substrate 10C to the side plate portion 25C. The substrates 10A and 10B are also reliably fixed to the side plate portions 25A and 25B in the similar manner. As illustrated in FIG. 12, each of the screws 70 penetrates the punched hole 27.

Each of the LED modules 30 includes an LED device 31, metal leads 32 and 33 spaced apart from each other, a wire 34 and a resin package 35. The LED modules 30 are mounted on each of the substrates 10A, 10B and 10C to be aligned in the axial direction x. The LED modules 30 mounted on the substrate 10A are exemplarily described below.

The LED device 31 may have a lamination structure made up of an n-type semiconductor layer, a p-type semiconductor layer and an active layer sandwiched between these layers. The LED device 31 can emit blue light when made of an AlGaInP-based semiconductor. The LED device 31 is mounted on the lead 32 arranged on one side of the substrate 10A in the width direction y. The upper surface of the LED device 31 is connected, via the wire 34, to the lead 33 arranged on the other side of the substrate 10A in the width direction.

The resin package 35 protects the LED device 31 and the wire 34. The resin package 35 is made of e.g. an epoxy resin that allows light emitted from the LED device 31 to pass therethrough. Mixing in the resin package 35 a fluorescent substance that emits yellow light when excited by blue light enables the LED module 30 to emit white light.

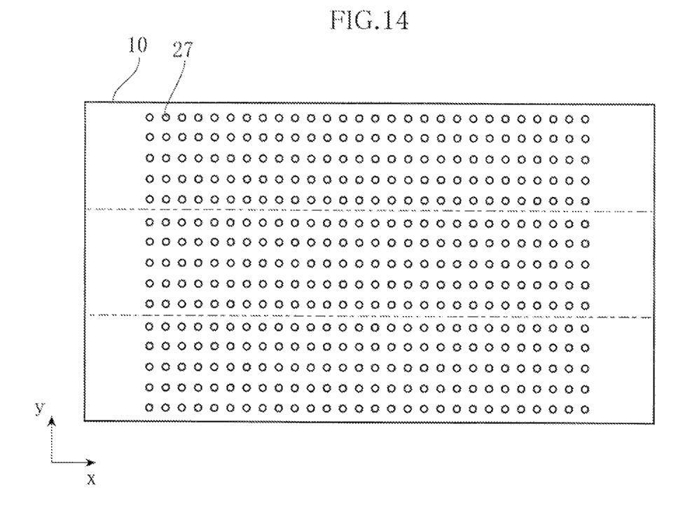

A method for manufacturing the LED lamp A4 is described below with reference to FIGS. 14-19.

First, as shown in FIG. 14, a metal plate 10 is prepared which has a thickness of 1 to 2 mm and a constant width in the width direction y, and is elongated in the axial direction x. For instance, the metal plate 10 is made of A1. Then, a plurality of punched holes 27 are formed in the metal plate 10 to be uniformly distributed. In this embodiment for example, 15 punched holes are aligned in the width direction y. Punched holes 27 are not formed in the regions adjacent to each end of the metal plate 10 in the axial direction x. The punched holes 27 can be easily formed by using e.g. a punch press machine.

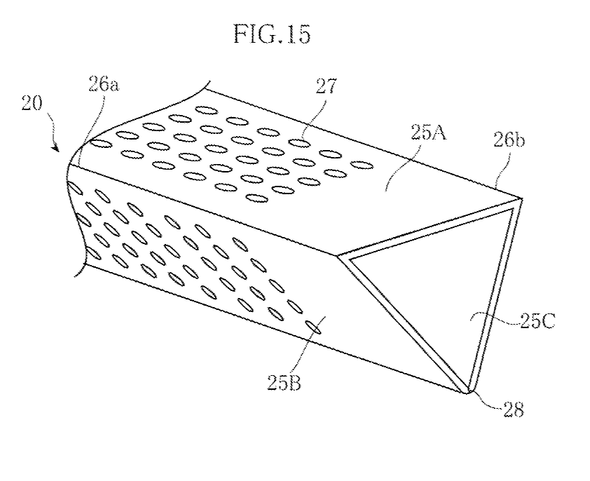

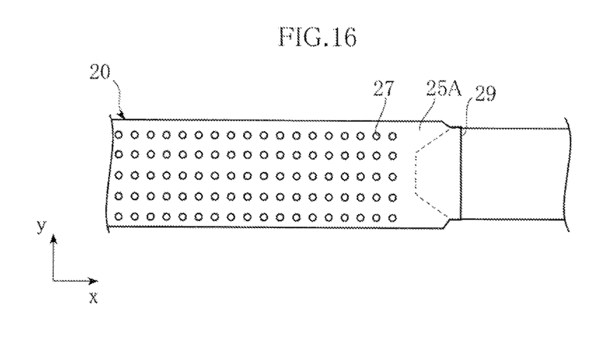

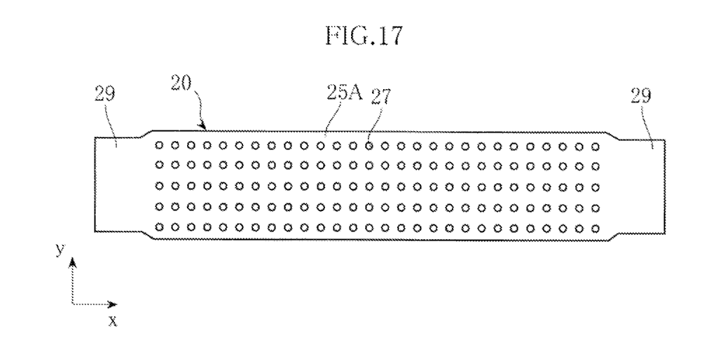

Then, a metal support member 20 is made from the metal plate 10. Specifically, in this process, the metal plate 10 is first bent 60° along two imaginary lines extending in the axial direction x and indicated in FIG. 14, whereby side plate portions 25A, 25B and 25C are formed. Then, the respective edges of the side plate portions 25B and 25C, which correspond to the two ends of the original metal plate 10 in the width direction y, are bonded together. Thus, a metal support member 20 shaped like a triangular tube as shown in FIG. 15 is obtained. The above-described bonding of the edges of the side plate portions 25B and 25C is performed by welding, for example. Then, as shown in FIG. 16, a cylindrical portion 29, which is annular as viewed in the axial direction x, is formed at an end of the metal support member 20. The cylindrical portion 29 is formed by pushing a rod, which is circular as viewed in the axial direction x, into an end of the metal support member 20 in the axial direction x. As shown in FIG. 17, a cylindrical portion 29 is formed also at the other end of the metal support member 20. The metal support member 20 of the LED lamp A4 is completed by the above-described process.

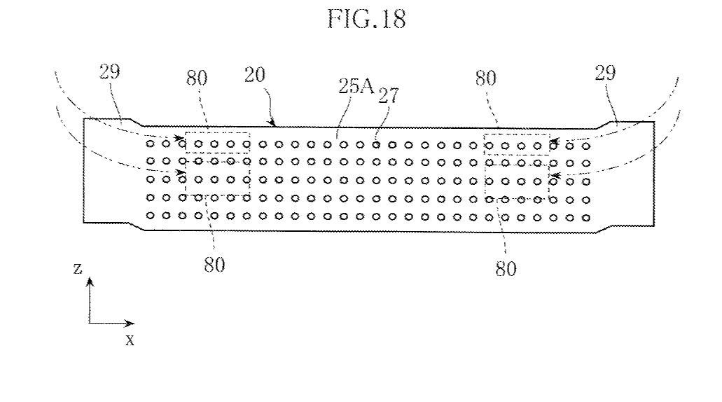

Then, Peltier devices 80 are mounted as shown in FIG. 18. Specifically in this process, six Peltier devices 80 are put into the metal support member 20 from the cylindrical portions 29, and two Peltier devices, for example, are bonded to each of the side plate portions 25A, 25B and 25C at appropriate portions of the inner surface. The Peltier devices 80 may be mounted before the metal plate 10 is bent.

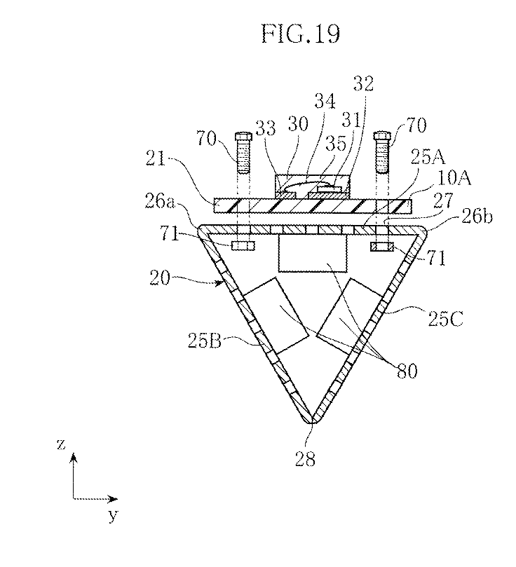

Then, as shown in FIG. 19, a substrate 10A is attached to the side plate portion 25A. It is to be noted that the substrate 10A has a plurality of LED modules 30 mounted thereon in advance. Specifically in this process, three screws 70 are inserted into the substrate 10A, and the screws 70 are then inserted through the punched holes 27. Thereafter, a nut 71 is attached to the end of each screw 70, whereby the substrate 10A is fixed to the side plate portion 25A. In the above-described process, one of the screws 70 is inserted into the substrate 10A at a central position in the axial direction x and close to an end in the width direction y, whereas the other two screws 70 are inserted in the substrate 10A at positions close to the two ends in the axial direction x and close to the other end in the width direction y.

Similarly to the attaching process of the substrate 10A, the substrate 10B and the substrate 10C are attached to the side plate portion 25B and the side plate portion 25c, respectively, whereby the LED lamp A4 shown in FIGS. 11-13 is completed.

The advantages of the LED lamp A4 are described below.

In the LED lamp A4, the LED modules 30 mounted respectively on the substrates 10A, 10B and 10C emit light in different directions. Thus, the LED lamp A4 can emit light similar to that of a fluorescent lamp and is hence suitable for use as a substitute for a tubular fluorescent lamp.

Since the substrates 10A, 10B and 10C are directly attached to the metal support member 20 made of a relatively thin single metal plate 10, the weight of the lamp is relatively small. The provision of the punched holes 27 in the side plate portions 25A, 25B and 25C also contributes to the reduction in weight of the LED lamp A4.

Since the metal support member 20 of this embodiment is formed with a plurality of punched holes 27 and hollow, the metal support member also functions effectively as a heat dissipation member for cooling the heat generated from the LED modules 30. The provision of the Peltier devices 80 on the inner surfaces of the side plate portions 25A, 25B and 25C further cools the substrates 10A, 10B and 10C effectively. Thus, the temperature of the substrates 10A, 10B, 10C and the LED modules 30 does not rise excessively, so that the LED lamp A4 is unlikely to break down and provides stable illumination.

Moreover, in this embodiment, since each end of the metal support member 20 in the axial direction x is provided with the cylindrical portion 29, a cylindrical base used for fluorescent lighting fixtures for general purpose lighting can be easily attached. Thus, the LED lamp A9 is suitable for use as a substitute for a straight-tube fluorescent lamp.

In this embodiment, the metal support member 20 is easily formed by bending a metal plate 10 and welding the two edges together. Thus, the manufacturing process is simple, and the manufacturing cost can be reduced.

In this embodiment, in fixing the substrates 10A, 10B and 10C to the side plate portions 25A, 25B and 25C with screws 70, the punched holes 27 formed in advance are utilized. Thus, the attaching work is facilitated.

The LED lamp according to the present invention is not limited to the foregoing embodiment. The specific structure of each part of the LED lamp according to the present invention can be varied in design in various ways. For instance, although the metal support member 20 in the foregoing embodiment is substantially shaped like a triangular tube, the metal support member may have a tubular shape having other polygonal cross sections such as a rectangular cross section.

Although the LED lamp A4 of the foregoing embodiment is structured as a substitute for a straight-tube fluorescent lamp, an LED lamp usable as a substitute for a circular fluorescent lamp can also be provided according to the present invention. This can be achieved by disposing a plurality of LED lamps each having a relatively short metal support member 20 in an annular arrangement.

1. An LED lamp elongated in an axial direction, comprising a plurality of LED chips,
wherein each of the LED chips is arranged to emit light having a main light irradiation direction directed outwards of a radial direction perpendicular to the axial direction, and
wherein the main light irradiation directions of the LED chips are different from each other as viewed in the axial direction.

2. The LED lamp according to claim 1, further comprising a metal support member supporting the LED chips and arranged inwards of the radial directions with respect to the LED chips.

3. The LED lamp according to claim 2, further comprising a reflective surface, wherein the radial directions include a first direction passing through one of the LED chips, and the reflective surface is configured to, as receding in the first direction, become farther away from said one of the LED chips in a second direction perpendicular to the first direction.

4. The LED lamp according to claim 3, further comprising a reflective member made of a metal and provided with the reflective surface,
wherein the reflective member and the metal support member are connected to each other.

5. The LED lamp according to claim 1, comprising at least one multiple light source in which at least two LED chips having different main light irradiation directions, among the plurality of LED chips, are arranged at a same position in the axial direction.

6. The LED lamp according to claim 5, comprising a plurality of multiple light sources spaced apart from each other in the axial direction.
